(19) United States
(12) Patent Application Publication
(10) Pub. No.: US 2007/0041440 A1
(43) Pub. Date: Feb. 22, 2007

(54) Method and device for echo cancellation

(75) Inventors: Dietmar Schoenbeck, Geofls (AT); Friedrich Kaufmann, Feldkirch (AT)

Correspondence Address: TAROLLI, SUNDHEIM, COVELL & TUMMINO L.L.P., 1300 EAST NINTH STREET, SUITE 1700, CLEVEVLAND, OH, 44114, US

(73) Assignee: Harris Corporation

(21) Appl. No.: 11/491,734

(22) Filed: Jul. 24, 2006

Related U.S. Application Data
(60) Provisional application No. 60/703,427, filed on Jul. 29, 2005.

(30) Foreign Application Priority Data
Jul. 25, 2005 (EP) 05 106 823.7

(51) Int. Cl. H03K 5/159; H03H 7/40; H04B 3/20; H03H 7/30

(52) U.S. Cl. 375/235; 370/286

(57) ABSTRACT

The invention relates to a repeater and a method for re-transmitting single frequency signals, in particular of the type used in single frequency signal repeaters for use in single frequency networks (SFNs) like digital video/audio broadcasting (DVB/DAB) networks. The estimation of echo feedback is derived from the measured power density spectrum with an inclusion of a variable phase shifter (57) in the signal path. Preferably, the phase shifter (57) is controlled by control means (56), which also set the adaptive filter (54) for feedback compensation, such that a signal coupled from the transmitter antenna back to the receiver antenna can substantially be cancelled out. The method according to the invention exhibits quick and stable regulation behavior and the re-transmitted signal does not suffer from degradation due to added interference. The quality of the signal at the transmitter antenna is improved even if dynamically changing feedback paths from the transmitter to the receiver antenna exist. The transmitter output power can be increased without increasing the risk of system instabilities, such as oscillations.

The invention relates to a method for re-transmitting single frequency signals, in particular of the type used in single frequency signal repeaters (so called gap fillers) for use in single frequency networks (SFNs) like digital video/audio broadcasting (DVB/DAB) networks.

In the following, the invention will be described for a gap filler in a terrestrial DVB (DVB-T) application. It should however be noted that the scope of the present invention is not limited to this application but can be applied to any SFN repeater, in particular to mobile telephone repeaters or the like.

In DVB-T broadcasting networks the propagation of Coded Orthogonal Frequency Division Multiplexing (COFDM) signals, which are generally used, is crucial for correct transmission, as the reception of such signals may change very abruptly from practically error free reception to a loss of signal (LOS) condition.

Therefore, during DVB-T coverage planning, steps have to be taken to avoid shadowed areas, in which the signal strength used to be high enough for analogue TV reception but may be insufficient for DVB-T reception. The same applies to indoor DVB-T reception, this being even more critical if compared to the conditions under which satisfying indoor analogue TV reception is possible.

Under these conditions, the use of re-transmitters (repeaters), which broadcast the DVB-T signal into shadowed areas is necessary in order to fulfil the increased and more complex coverage requirements posed by commercial terrestrial distribution of digital TV.

Despite their propagation constraints, COFDM signals are preferred for digital TV broadcasting, since the problem of interference between adjacent channels, as known from analogue TV broadcasting, is inherently avoided. Thus, DVB-T broadcasting networks are preferably planned as single frequency networks, in which a unique frequency is used all over a specific coverage area leading to an increased spectral efficiency of the network.

However, as explained above, these DVB-T single frequency networks require the use of single or iso-frequency repeaters, which are also referred to as gap fillers, i.e. radio-frequency repeaters receiving and transmitting at substantially the same frequency.

One of the most significant design constraints of such single frequency repeaters results from the effect that they receive and transmit signals at the same frequency, which leads to an inevitable signal coupling between the transmitting and the receiving antenna. Reception of a transmitter signal by the antenna of the receiver (echo) can lead to instability of the repeater, such as oscillation. In repeaters according to the state of the art, such back coupling or echoes set an upper limit for the maximum allowed gain of the repeater, which in turn limits the coverage area.

One conceivable way to minimize the risk of instabilities in repeaters is to increase isolation between the transmitting and receiving antennas. However, besides increased costs involved with more sophisticated isolation means, increasing isolation only represents a sub-optimal solution, since—at least to some extent—the back coupling, and with it the echoes, remain.

The back coupling problem may even aggravate when considering moving objects (e.g. vehicles), which can act as a reflector for the transmitted signal resulting in a dynamically changing back coupling between the transmitting and the receiving antenna, and which can, of course, not be taken into account at the time of designing the repeater. Therefore, such dynamic back coupling effects cannot be avoided by isolation measures taken in the repeater.

Thus, it is an object of the present invention to provide a method for re-transmitting signals, particularly single frequency signals, as well as a repeater, which reduce the echo signal propagation within the single frequency repeater, particularly with respect to dynamically changing echoes.

It is another object of the present invention to increase the limit for the maximum allowed gain of the repeater or the method of re-transmitting signals, particularly single frequency signals, while maintaining operation of the repeater stable and reliable.

It is further an object of the present invention to maximize the coverage area in a single frequency network or to cover a certain area of a single frequency network with a reduced number of repeaters.

These objects are solved by a method with the features of claim 1 as well as a repeater with the features of claim 15. Preferred embodiments and improvements are subject matter of the respective dependent claims.

According to the present invention, the method for re-transmitting single frequency signals, particularly of the type used in single frequency signal repeaters for use in single frequency networks like digital video/audio broadcasting (DVB/DAB) networks, comprises the following steps:

A receiving step, in which a first single frequency signal is received by means of at least one first antenna. Optionally, this first single frequency signal is converted to another frequency, preferably by down-mixing to an intermediate frequency (IF) signal.

In a first filtering step, the first single frequency signal x or the IF signal x is filtered to result in a filtered input signal l. Preferably, a band-pass filter is used for the input signal filtering, which lets pass substantially only the first single frequency signal or the IF signal, respectively.

In an optional first amplification step, said filtered input signal l is amplified to result in an amplified input signal. Preferably, the amplification gain is controlled automatically to produce a substantially constant amplitude of said amplified input signal.

Amplifying the input signal is particularly useful in order to use the full conversion scale in an optional subsequent quantization step, in which said amplified input signal or said filtered input signal l is quantized to result in a quantized input signal. Preferably, the quantization step uses conventional analogue-to-digital conversion in order to benefit from the advantages of digital signal processing of the amplified input signal or the filtered input signal l, respectively, in subsequent steps.

In an optional demodulation step, said amplified input signal, said filtered input signal l and/or said quantized input signal is demodulated to result in a demodulated input signal.

In an equalizing step said filtered input, amplified, quantized and/or demodulated input signal is equalized to produce an equalized signal (processing signal m). The equalization step according to the method of the invention at least minimizes a back coupling signal a between said first and second antenna. Preferably, in order to achieve this, said processing signal m is at least partially analyzed.

In a cancellation step, a cancellation signal f is generated based on said processing signal m. Preferably, this is done by using the result of said analysis of the processing signal m. Further, in a feedback step, said cancellation signal f is then fed back to said processing signal m for echo cancellation.

Further, in a conversion step, said processing signal m is converted into a second single frequency signal, preferably of substantially the same frequency as said first single frequency signal.

According to the present invention, the equalization step further comprises controlled phase shifting of said processing signal m by at least one predetermined phase angle Ψ. Preferably, said phase shifting is controlled using the result of said analysis of the processing signal m.

In a second filtering step, said second single frequency signal is filtered to result in a filtered second single frequency signal. Preferably, as in the case of the first single frequency signal, a band-pass filter is used which lets pass substantially only the second single frequency signal.

In a second amplification step according to the invention, said filtered second single frequency signal is amplified to produce an amplified second single frequency signal for further transmission. In a transmission step, said amplified second single frequency signal is transmitted by means of at least one second antenna.

The integration of phase shifting in the equalization step has several advantages, if compared to prior art single frequency re-transmitting solutions. Firstly, it permits higher accuracy in echo estimation than do solutions, which solely rely on uncorrelated measurements of the power density spectrum of the received signal. Secondly, the higher accuracy of the echo estimation can be used to increase the speed in which the cancellation function or filter can adapt to a change in the coupling between the transmitting and receiving antenna.

Most important, the superior cancellation performance of a re-transmitting solutions according to the present invention can—for a given limited isolation between transmitting and receiving antenna—be used to increase the output signal gain without the risk of increasing the echo signal level that is received from the transmitting antenna and which could cause the repeater to become unstable.

In a preferred embodiment of the method according to the invention, said cancellation signal f is generated based on said processing signal m using an adaptive filter with a transfer function F(z).

In another preferred embodiment of the method according to the invention, said equalization step comprises capturing said filtered input, amplified, quantized and/or demodulated input signal, continuously or at predetermined points in time, resulting in a captured signal c.

In another preferred embodiment of the method according to the invention, said equalization step comprises analyzing the captured signal c and controlling said phase shifting using the result of said analysis of the captured signal c.

In yet another preferred embodiment of the method according to the invention, said equalization step comprises controlling the generation of said cancellation signal f using the result of said analysis of the captured signal c.

Preferably, said equalization step comprises delaying said processing signal m by at least one, preferably by a set of predetermined and most preferably fixed time intervals T to form the basis of said cancellation signal f.

Thus, said equalization step uses said predetermined delayed instances of the processing signal m, which are multiplied with (filter) coefficients, most preferably adaptive (filter) coefficients, summed up and fed back as cancellation signal f to the processing signal m to cancel out signal distortions (quantized/decision feedback equalization), particularly echoes resulting from back coupling of the transmitted signal. When the processing signal m is digital, the cancellation signal f has to be digital-to-analogue converted and fed back to a point in the signal path before the processing signal m is digitized.

Preferably, said equalization step further comprises controlling said delay(s) and/or said (decision feedback filter) coefficients using the result of said analysis of the captured signal c.

In a particularly preferred embodiment of the method according to the invention, said equalization step comprises measuring the spectral power densities |M|² of said processing signal m for at least two, preferably three values of Ψ, and most preferably for

$$Ψ ∈ \{ 0 , \frac{2 π}{3} , \frac{4 π}{3} \} ,$$

resulting in the corresponding spectral power densities |M_{A}|², |M_{B}|² and |M_{C}|² of said processing signal m.

In another preferred embodiment of the method according to the invention, said cancellation signal f is generated by adaptively filtering said processing signal m shifted in phase by Ψ (phase shifted processing signal y) using said transfer function F(z). Particularly preferably, the phase shift angle Ψ is ±2π/3, however, any other phase shift angle Ψ may also be used within the scope of the present invention.

In yet another preferred embodiment of the method according to the invention, said first single frequency signal x or said IF signal x, respectively, has a spectral function X(z), said signal coupling between said first and second antenna has a transfer function A(z), said input filtering has a transfer function H(z), said phase shifting can be expressed by a transfer function e^{jΨ}, said processing signal has a spectral function M(z) and said processing signal shifted in phase has a spectral function Y(z), wherein said spectral function M(z) can be expressed as
M=X·H+Y·A·H−Y·F, with Y=M·e^{jΨ}.
It follows that

$$M = X \cdot H + M \cdot {ⅇ}^{jΨ } \cdot ( A \cdot H - F )$$

$$or$$

$$M = X \cdot \frac{H}{1 - {ⅇ}^{jΨ} ( H \cdot A - F )} = X \cdot \frac{H}{1 - {ⅇ}^{jΨ} Δ} , \\ with$$

$$Δ = H \cdot A - F = r \cdot {ⅇ}^{jΨ} .$$

In another particularly preferred embodiment of the method according to the invention, said equalization step comprises using a help function T, where

$$T = \frac{\frac{1}{{\vert {M}_{A} \vert}^{2}} + \frac{1}{{\vert {M}_{B} \vert}^{2}} \cdot {ⅇ}^{- j \frac{2 π}{3}} + \frac{1}{{\vert {M}_{C} \vert}^{2}} \cdot {ⅇ}^{- j \frac{4 π}{3}}}{\frac{1}{{\vert {M}_{A} \vert}^{2}} + \frac{1}{{\vert {M}_{B} \vert}^{2}} + \frac{1}{{\vert {M}_{C} \vert}^{2}}}$$

is based on said measured spectral power densities |M_{A}|², |M_{B}|² and |M_{C}|² of said processing signal m, for determining and minimizing

$$Δ = \frac{- 2 \cdot T}{1 + \sqrt{1 - 4 \cdot {\vert T \vert}^{2}}} = H \cdot A - F ,$$

i.e. cancelling the echo feedback signal H·A, to yield

$$M = X \cdot \frac{H}{1 - {ⅇ}^{jΨ} Δ} {⟶}^{Δ -> 0} X \cdot H$$

by iteratively adapting said filter transfer function F(z), wherein an accordingly modified impulse response fᵢ₊₁=fᵢ+δ of said filtering step results from the addition of δ, i.e. the inverse Fourier transform of Δ, δ=iFFT(Δ), to the former impulse response fᵢ of said filtering step.

In a preferred embodiment of the method according to the invention, during an initialization step a training signal sequence d, which is preferably a pseudo-random sequence, is used as input signal x to obtain an initial value f₁ of the impulse response fᵢ of said adaptive filtering step.

Preferably, said adaptive filtering step uses a differential signal e between said captured processing signal c and said training signal sequence d, which is delayed according to the delay of said captured processing signal c with respect to said input signal, as a criterion to optimize the filter coefficients of said adaptive filtering step by minimizing the power of said difference signal e being proportional to its spectral power density |E|² (Minimum Mean Square Error algorithm).

In another preferred embodiment of the method according to the invention, said adaptive filtering step involves an optimization algorithm selected from a group including a Least Mean Squares (LMS) algorithm, a steepest descent algorithm, a differential steepest descent algorithm, a gradient algorithm, a stochastic gradient algorithm and a Recursive Least Squares (RLS) algorithm.

The repeater for single frequency signals according to the present invention comprises at least one first antenna, which receives a first single frequency signal. Optionally, a converter is provided which converts said first single frequency signal to another frequency, preferably by down-mixing to an IF signal.

The repeater according to the invention has an input filter, preferably a band-pass filter, which filters said first single frequency signal x or said IF signal x, respectively, to result in a filtered input signal l.

Optionally, an input amplifier is provided, which amplifies said filtered input signal l to result in an amplified input signal. Preferably an automatic gain control amplifier (AGC) is used, which controls the amplification gain automatically to produce a substantially constant amplitude of said amplified input signal.

In a preferred embodiment of the repeater according to the invention, a quantizer is provided following the AGC in the signal path. Preferably, an analogue-to-digital converter is used as quantizer, which quantizes said amplified input signal, to result in a quantized input signal.

In another preferred embodiment of the repeater, a demodulator demodulates said amplified input signal, said filtered input signal or said quantized input signal to result in a demodulated input signal.

The repeater according to the invention further comprises an equalizer, which equalizes said filtered, amplified, quantized and/or demodulated input signal (processing signal m).

Moreover, in the repeater according to the invention, a converter is provided, which converts said processing signal m to result in a second single frequency signal, the second single frequency signal preferably having the substantially same frequency as the first single frequency signal. An output filter filters said second single frequency signal to result in a filtered second single frequency signal, which is then amplified by an output amplifier to result in an amplified second single frequency signal. Finally, at least one second antenna (re-)transmits said amplified second single frequency signal.

In the repeater according to the present invention said equalizer is equipped so as to at least reduce a coupling signal a between said first and second antenna. Optionally, for this purpose, analyzer means are provided, which at least partially analyze said processing signal m.

Furthermore, signal generator means generate a cancellation signal f based on said processing signal m, preferably by using the result of said analysis of the processing signal m. Said cancellation signal f is fed back to said processing signal m by feed-back means. According to the present invention, said equalizer further comprises a variable phase shifter which shifts the phase of said processing signal m by a at least one predetermined phase angle Ψ. Preferably, said phase shifter is controlled using the result of said analysis of the processing signal m.

Other preferred repeaters according to the present invention use at least one of the methods for re-transmitting a signal and particularly a single frequency signals as described above in order to minimize echoes resulting from a back coupling of the re-transmitted signal to the receiving antenna of the repeater.

Additional features and advantages of the present invention may be taken from the following detailed description of a particularly preferred embodiment with reference to the drawings, in which

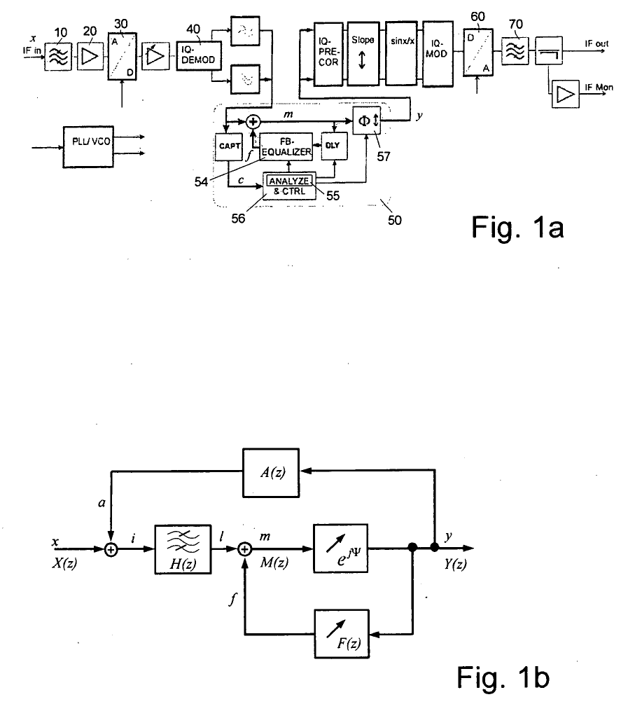

FIG. 1a shows a schematic block diagram of a repeater using the method according to the present invention;

FIG. 1b shows a schematic signal flow diagram of a repeater using the method according to the present invention;

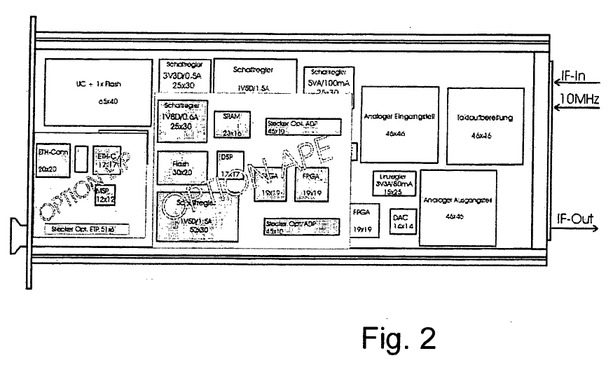

FIG. 2 shows a schematic board layout of a repeater using the method according to the present invention;

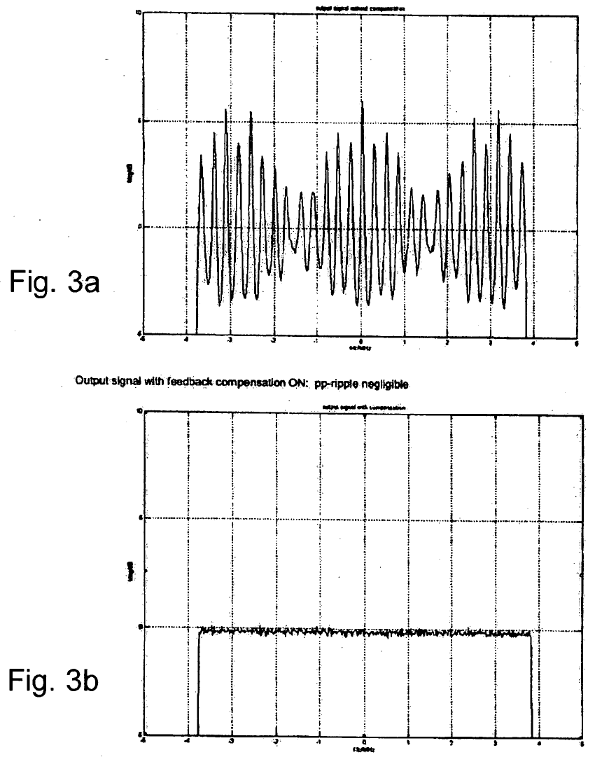

FIG. 3a shows a diagram of the amplitude run of the simulated output signal spectrum with respect to the carrier frequency for a first set of coupling paths without input signal ripple and without echo cancellation;

FIG. 3b shows a diagram of the amplitude run of the simulated output signal spectrum according to FIG. 3a using echo cancellation according to the invention;

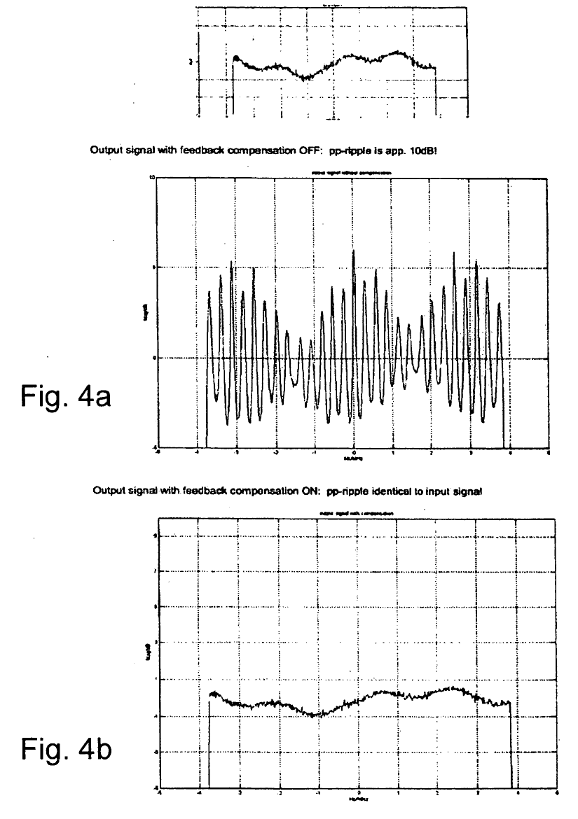

FIG. 4a shows a diagram of the amplitude run of the simulated output signal spectrum with respect to the carrier frequency for a second set of coupling paths with input signal ripple and without echo cancellation;

FIG. 4b shows a diagram of the amplitude run of the simulated output signal spectrum according to FIG. 4a using echo cancellation according to the invention;

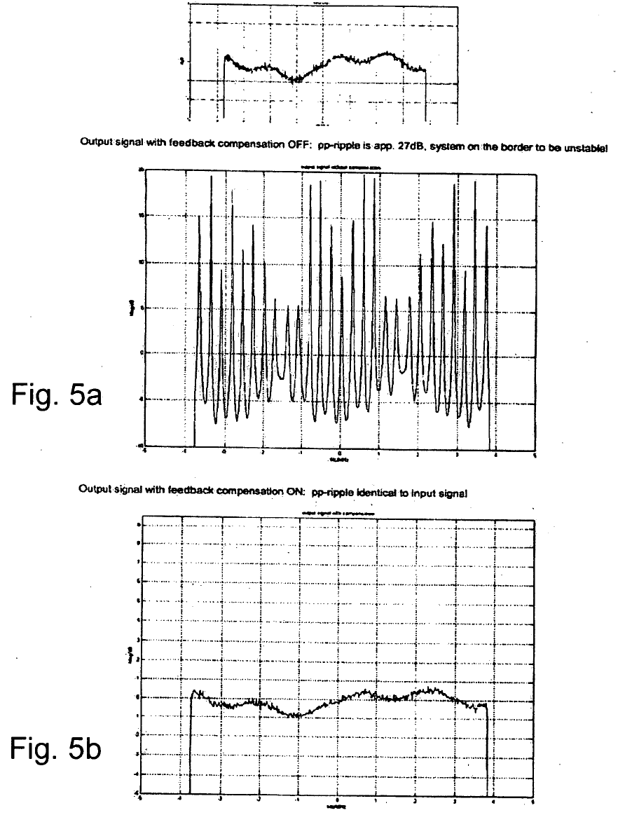

FIG. 5a shows a diagram of the amplitude run of the simulated output signal spectrum with respect to the carrier frequency for a third set of coupling paths with input signal ripple and without echo cancellation;

FIG. 5b shows a diagram of the amplitude run of the simulated output signal spectrum according to FIG. 5a using echo cancellation according to the invention.

FIG. 1a shows a preferred embodiment of a repeater using the method of re-transmitting according to the present invention. The input signal x is filtered by the band-pass filter 10 before being amplified by the automatic gain control amplifier 20. This has the advantage that the full conversion scale of the subsequent analogue-to-digital converter 30 can be used. Consecutively, an IQ-demodulator 40 is used to demodulate the digitized output signal of the analogue-to-digital converter 30.

In the embodiment of FIG. 1a, the subsequent equalizer 50 makes use of a digital feedback filter 54. For this, the processing signal m is firstly delayed and then serves as an input signal for the feedback filter 54. In addition, the demodulated output signal of the IQ-demodulator 40 is captured to result in the captured signal c, which is analyzed by the analyzing means 55. The analysis results are used by the control means 56 for controlling the filter coefficients of the feedback filter 54, the delay element and the phase shifter 57.

Following this, the phase shifted processing signal y is fed to an IQ-modulator, in which an IQ-modulation of the equalized signal is performed. The modulated signal is then converted back to the analogue domain by the digital-to-analogue converter 60 before being filtered by the band-pass filter 70 and transmitted to the transmitting antenna.

FIG. 1b shows a signal flow diagram of a preferred embodiment of the method according the invention, in which the first single frequency signal x or IF signal x, respectively, has a spectral function X(z), the signal coupling between said first and second antenna has a transfer function A(z), the band-pass filter filtering said signal x has a transfer function H(z), the phase shifting is expressed by a transfer function e^{jΨ}, the processing signal has a spectral function M(z) and the phase shifted processing signal has a spectral function Y(z), wherein said spectral function M(z) can be expressed as
M=X·H+Y·A·H−Y·F with Y=M·e^{jΨ}.
It follows that

$$M = X \cdot H + M \cdot {ⅇ}^{φΨ} \cdot ( A \cdot H - F )$$

$$or$$

$$M = X \cdot \frac{H}{1 - {ⅇ}^{jΨ} ( H \cdot A - F )} = X \cdot \frac{H}{1 - {ⅇ}^{jΨ} Δ} ,$$

wherein the complex overall feedback transfer function is denoted as Δ=r·e^{jφ}.

The aim is to minimize or completely cancel out the overall feedback Δ by iteratively adapting the filter coefficients of the cancellation filter with the transfer function F(z).

It is now shown that an estimate for the overall feedback Δ for efficient dynamic echo cancellation can be achieved very effectively by phase shifting of the processing signal m by a phase angle Ψ.

In a preferred embodiment of the method according to the invention, the spectral power densities |M|² of the processing signal m are measured for

$$Ψ ∈ \{ 0 , \frac{2 π}{3} , \frac{4 π}{3} \} .$$

This results in the corresponding spectral power densities |M_{A}|², |M_{B}|² and |M_{C}|² of said processing signal m.

With

$$M = X \cdot \frac{H}{1 - {ⅇ}^{jΨ} Δ}$$

and Y=M·e^{jΨ}, the spectral power density |M|² of the processing signal m becomes

$${\vert M \vert}^{2} = {\vert Y \vert}^{2} = {\vert X \vert}^{2} \cdot \frac{{\vert H \vert}^{2}}{{\vert 1 - {ⅇ}^{jΨ} Δ \vert}^{2}}$$

with the unknown overall feedback Δ=r·e^{jφ}. This leads to

$$\frac{1}{{\vert M \vert}^{2}} = \frac{1}{{\vert X \vert}^{2}} \cdot \frac{1}{{\vert H \vert}^{2}} \cdot [ 1 + {r}^{2} - 2 r cos ( φ + Ψ ) ] .$$

For

$$Ψ ∈ \{ 0 , \frac{2 π}{3} , \frac{4 π}{3} \} ,$$

the mean spectral power density |M₀|² can be calculated from

$$\frac{1}{{\vert {M}_{0} \vert}^{2}} = \frac{1}{3} \cdot [ \frac{1}{{\vert {M}_{A} \vert}^{2}} + \frac{1}{{\vert {M}_{B} \vert}^{2}} + \frac{1}{{\vert {M}_{C} \vert}^{2}} ] . \\ With$$

$$\frac{1}{{\vert M \vert}^{2}} = \frac{1}{{\vert X \vert}^{2}} \cdot \frac{1}{{\vert H \vert}^{2}} \cdot [ 1 + {r}^{2} - 2 r cos ( φ + Ψ ) ]$$

$$this leads to$$

$$\frac{1}{{\vert {M}_{0} \vert}^{2}} = \frac{1 + {r}^{2}}{{\vert X \vert}^{2} \cdot {\vert H \vert}^{2}} .$$

$$It follows that$$

$$\frac{{\vert {M}_{0} \vert}^{2}}{{\vert M \vert}^{2}} = 1 - \frac{2 r}{1 + {r}^{2}} cos ( φ + Ψ )$$

$$and$$

$$\frac{{\vert {M}_{0} \vert}^{2}}{{\vert {M}_{A} \vert}^{2}} = 1 - \frac{2 r}{1 + {r}^{2}} cos ( φ ) , \\ \frac{{\vert {M}_{0} \vert}^{2}}{{\vert {M}_{B} \vert}^{2}} = 1 - \frac{2 r}{1 + {r}^{2}} cos ( φ + \frac{2 π}{3} ) , \\ \frac{{\vert {M}_{0} \vert}^{2}}{{\vert {M}_{C} \vert}^{2}} = 1 - \frac{2 r}{1 + {r}^{2}} cos ( φ - \frac{2 π}{3} ) .$$

Using the above results the help function

$$T = \frac{\frac{1}{{\vert {M}_{A} \vert}^{2}} + \frac{1}{{\vert {M}_{B} \vert}^{2}} \cdot {ⅇ}^{- j \frac{2 π}{3}} + \frac{1}{{\vert {M}_{C} \vert}^{2}} \cdot {ⅇ}^{- j \frac{4 π}{3}}}{\frac{1}{{\vert {M}_{A} \vert}^{2}} + \frac{1}{{\vert {M}_{B} \vert}^{2}} + \frac{1}{{\vert {M}_{C} \vert}^{2}}}$$

becomes

$$T = \frac{{\vert {M}_{0} \vert}^{2}}{3} \cdot [ \frac{1}{{\vert {M}_{A} \vert}^{2}} + \frac{1}{{\vert {M}_{B} \vert}^{2}} \cdot {ⅇ}^{- j \frac{2 π}{3}} + \frac{1}{{\vert {M}_{C} \vert}^{2}} \cdot {ⅇ}^{- j \frac{4 π}{3}} ] .$$

This leads to

$$3 T = 1 - \frac{2 r}{1 + {r}^{2}} cos φ + [ 1 - \frac{2 r}{1 + {r}^{2}} cos ( φ + \frac{2 π}{3} ) ] \cdot {ⅇ}^{- j \frac{2 π}{3}} + [ 1 - \frac{2 r}{1 + {r}^{2}} cos ( φ - \frac{2 π}{3} ) ] \cdot {ⅇ}^{j \frac{2 π}{3}} ,$$

which can be simplified to

$$3 T = 1 - \frac{2 r}{1 + {r}^{2}} cos φ + {ⅇ}^{- j \frac{2 π}{3}} + {ⅇ}^{j \frac{2 π}{3}} - \frac{2 r}{1 + {r}^{2}} cos φ \cdot cos \frac{2 π}{3} \cdot [ {ⅇ}^{- j \frac{2 π}{3}} + {ⅇ}^{j \frac{2 π}{3}} ] - \frac{2 r}{1 + {r}^{2}} sin φ \cdot sin \frac{2 π}{3} \cdot [ {ⅇ}^{- j \frac{2 π}{3}} - {ⅇ}^{j \frac{2 π}{3}} ]$$

and further to

$$\begin{matrix}3 T = \frac{2 r}{1 + {r}^{2}} \cdot [ - cos φ + cos φ \cdot ( \frac{1}{2} ) - sin φ \cdot \frac{\sqrt{3}}{2} \cdot 2 j \cdot \frac{\sqrt{3}}{2} ] \\ = \frac{2 r}{1 + {r}^{2}} \cdot [ - \frac{3}{2} cos φ \cdot - j \cdot \frac{3}{2} sin φ ]\end{matrix}$$

ultimately becoming

$$T = \frac{- r}{1 + {r}^{2}} \cdot {ⅇ}^{jφ}$$

Thus, it follows for the unknown phase φ of the overall feedback φ=arg(−T). This means that φ can be derived from the measured spectral power densities |M_{A}|², |M_{B}|² and |M_{C}|² of the processing signal m as

$$φ = arg [ - \frac{\frac{1}{{\vert {M}_{A} \vert}^{2}} + \frac{1}{{\vert {M}_{B} \vert}^{2}} \cdot {ⅇ}^{- j \frac{2 π}{3}} + \frac{1}{{\vert {M}_{C} \vert}^{2}} \cdot {ⅇ}^{- j \frac{4 π}{3}}}{\frac{1}{{\vert {M}_{A} \vert}^{2}} + \frac{1}{{\vert {M}_{B} \vert}^{2}} + \frac{1}{{\vert {M}_{C} \vert}^{2}}} ] .$$

Furthermore,

$$\vert T \vert = \vert \frac{r}{1 + {r}^{2}} \vert$$

leads to

$${r}_{1 , 2} = \frac{1 \pm \sqrt{1 - 4 \cdot {\vert T \vert}^{2}}}{2 \cdot \vert T \vert}$$

for r>0.
As r shall have a small value, i.e. r<1, the negative signed solution is pertinent, such that

$$r = \frac{1 - \sqrt{1 - 4 \cdot {\vert T \vert}^{2}}}{2 \cdot \vert T \vert} = \frac{2 \cdot \vert T \vert}{1 + \sqrt{1 - 4 \cdot {\vert T \vert}^{2}}} .$$

The unknown overall feedback

$$Δ = r \cdot {ⅇ}^{jφ} = \frac{2 \cdot \vert T \vert}{1 + \sqrt{1 - 4 \cdot {\vert T \vert}^{2}}} \cdot {ⅇ}^{j arg ( - T )} = \frac{2 \cdot \vert T \vert}{1 + \sqrt{1 - 4 \cdot {\vert T \vert}^{2}}}$$

can now be estimated based on the help function T which is defined by said measured spectral power densities |M_{A}|², |M_{B}|² and |M_{C}|² of the processing signal m.

This estimation based on the controlled phase shifting step as part of the equalization according to the present invention can be used for determining and minimizing

$$Δ = \frac{2 \cdot \vert T \vert}{1 + \sqrt{1 - 4 \cdot {\vert T \vert}^{2}}} = H \cdot A - F ,$$

i.e. for cancelling the echo feedback signal H·A, to yield

$$M = X \cdot \frac{H}{1 - {ⅇ}^{jψ} Δ} {⟶}^{Δ \to 0} X \cdot H$$

by iteratively adapting said filter transfer function F(z), wherein an accordingly modified impulse response fᵢ₊₁=fᵢ+δ of the filtering step results from the addition of δ, i.e. the inverse Fourier transform of Δ, δ=iFFT(Δ).

FIG. 2 shows a schematic slot-in board layout of an embodiment of a repeater according to the invention with IF input and output ports as well as a clock input.

FIG. 3a shows a diagram of the amplitude run of a simulated 8 MHz output signal spectrum with respect to the DVB-T carrier frequency for a first triplet of coupling paths without input signal ripple and without echo cancellation. The coupling paths' parameters are as follows:

Path 1: gain margin=10.5 dB, delay=120 ns

Path 2: gain margin=16.5 dB, delay=450 ns

Path 3: gain margin=24.4 dB, delay=1650 μs

As can be taken from FIG. 3a, without feedback compensation based on the three different feedback paths, the output signal suffers from a strong output ripple of approximately 10 dB, which means that echoes already cause instabilities in the repeater.

FIG. 3b sows a simulation result using the same simulation parameters, however, with echo cancellation switched on. As can be taken from FIG. 3b the feedback compensation according to the present invention effectively cancels output ripple and thus avoids an unstable operation of the repeater. In turn, the output power of the repeater according to this embodiment of the invention can be increased by about 10 dB, which typically leads to a larger coverage area.

FIG. 4a shows a diagram of the amplitude run of a simulated 8 MHz output signal spectrum with respect to the DVB-T carrier frequency for a second triplet of coupling paths with input signal ripple of approximately 1.5 dB and without echo cancellation. The coupling paths' parameters are identical to the parameters of the embodiment referred to in FIGS. 3a and 3b.

As can be seen in FIG. 4a, without feedback compensation the output signal also suffers from a strong output ripple of approximately 10 dB. In contrast thereto, FIG. 4b sows a simulation result using the same simulation parameters, however, with echo cancellation switched on.

As can be taken from FIG. 4b the feedback compensation according to the present invention effectively cancels output ripple resulting from echoes and thus warrants for a stable operation of the repeater and accurate replication of the input signal. Again, the output power of the repeater according to this embodiment of the invention can be increased by about 10 dB.

FIG. 5a shows a diagram of the amplitude run of a simulated 8 MHz output signal spectrum with respect to the DVB-T carrier frequency for a third triplet of coupling paths with input signal ripple of approximately 1.5 dB and without echo cancellation. The paths' parameters are as follows:

Path 1: gain margin=1.9 dB, delay=120 ns

Path 2: gain margin=8.9 dB, delay=450 ns

Path 3: gain margin=15.9 dB, delay=1650 μs

As can be taken from FIG. 5a, without feedback compensation based on the three different feedback paths, the output signal suffers from even stronger output ripple of approximately 27 dB, which means that the repeater is running unstable.

In contrast thereto, FIG. 5b sows a simulation result using the same simulation parameters, however, with echo cancellation switched on. As can be taken from FIG. 5b the feedback compensation according to the present invention effectively cancels output ripple resulting from echoes and warrants for a stable operation of the repeater and accurate replication of the input signal. Obviously, the output power of the repeater according to this embodiment of the invention can be increased by more than 10 dB without the risk of causing instabilities, such as oscillations.

1. Method for re-transmitting single frequency signals, particularly of the type used in single frequency signal repeaters for use in single frequency networks (SFNs) like digital video/audio broadcasting (DVB/DAB) networks, the method comprising the following steps:
receiving a first single frequency signal by means of at least one first antenna,
converting said first single frequency signal to another frequency, preferably by down-mixing it to an intermediate frequency (IF) signal,
input filtering said first single frequency or said IF signal, preferably by a band-pass filter, to produce a filter input signal,
amplifying said filtered input signal to produce an amplified input signal, preferably such that the amplification gain is controlled automatically to result in a substantially constant amplitude of said amplified input signal,
quantizing said amplified input signal, preferably by analogue-to-digital conversion to produce a quantized input signal,
demodulating said amplified input signal or said quantized input signal to produce a demodulated input signal,
equalizing said filtered, amplified, quantized and/or demodulated input signal to provide an equalized signal to provide an equalized signal, wherein said equalization at least reduces a coupling signal between said first and second antenna by generating a cancellation signal on the basis of said equalized signal, the cancellation signal being fed back to said equalized signal,
converting said equalized signal into a second single frequency signal, preferably of substantially the same frequency as said first single frequency signal,
filtering said second single frequency signal to produce a filtered second single frequency signal,
amplifying said filtered second single frequency signal to produce an amplified second single frequency signal,
transmitting said amplified second single frequency signal by means of at least one second antenna, and
said equalizing comprises controlled phase shifting of said equalized signal by at least one predetermined phase angle Ψ.

2. Method according to claim 1, wherein the equalized signal is at least partially analyzed and wherein the analysis results are used for the generation of the cancellation signal and/or the analysis results are used to control the phase shifting of the equalized signal.

3. Method according to claim 1, wherein said cancellation signal is generated based on said equalized signal using an adaptive filter with a transfer function F(z).

4. Method according to claim 1, wherein said equalization step comprises capturing said filtered, amplified, quantized and/or demodulated input signal continuously or at predetermined points in time to produce a captured signal.

5. Method according to claim 4, wherein said equalization step comprises analyzing the captured signal and controlling said phase shifting using the result of the analysis of said captured signal and/or controlling the generation of said cancellation signal using the result of the analysis of said captured signal.

6. Method according to claim 1, wherein said equalization step comprises delaying said equalized signal by at least one, preferably by a set of predetermined and/or fixed time intervals to form the basis of said cancellation signal.

7. Method according to claim 6, wherein said equalization step comprises controlling said delay by said analyzed captured signal.

8. Method according to claim 1, wherein said equalization step comprises measuring the spectral power densities |M|² of said equalized signal for at least two, preferably three values of Ψ, and most preferably for
$$ψ ∈ \{ 0 , \frac{2 π}{3} , \frac{4 π}{3} \}$$
resulting in the corresponding spectral power densities |M_{A}|², |M_{B}|² and |M_{C}|² of said equalized signal.

9. Method according to claim 8, wherein said cancellation signal is generated by adaptively filtering said equalized signal shifted in phase by Ψ (phase shifted equalized signal) using said transfer function F(z).

10. Method according to claim 8, wherein said first single frequency signal or said IF signal has a spectral function X(z), said signal coupling between said first and second antenna has a transfer function A(z), said input filtering has a transfer function H(z), said phase shifting can be expressed by a transfer function e^{jΨ}, said processing signal has a spectral function M(z) and said processing signal shifted in phase has a spectral function Y(z), wherein said spectral function M(z) can be expressed as
M=X·H+Y·A·H−Y·F, with Y=M·e^{jΨ.}
such that
$$M = X \cdot H + M \cdot {ⅇ}^{jψ} \cdot ( A \cdot H - F )$$
$$or$$
$$M = X \cdot \frac{H}{1 - {ⅇ}^{jψ} \cdot ( A \cdot H - F )} = X \cdot \frac{H}{1 - {ⅇ}^{jψ} Δ} ,$$
and wherein
Δ=H·A−F=R·e^{jΨ}.

11. Method according to claim 10, wherein said equalization step comprises using a help function T, where
$$T = \frac{\frac{1}{{\vert {M}_{A} \vert}^{2}} + \frac{1}{{\vert {M}_{B} \vert}^{2}} \cdot {ⅇ}^{- j \frac{2 π}{3}} + \frac{1}{{\vert {M}_{C} \vert}^{2}} \cdot {ⅇ}^{- j \frac{4 π}{3}}}{\frac{1}{{\vert {M}_{A} \vert}^{2}} + \frac{1}{{\vert {M}_{B} \vert}^{2}} + \frac{1}{{\vert {M}_{C} \vert}^{2}}}$$
based on said measured spectral power densities |M_{A}|², |M_{B}|² and |M_{C}|² of said equalized signal for determining and minimizing H·A to yield
$$M = X \cdot \frac{H}{1 - {ⅇ}^{jψ} Δ} {⟶}^{Δ \to )} X \cdot H$$
by iteratively adapting said filter transfer function F(z), wherein an accordingly modified impulse response fᵢ₊₁=fᵢ+δ of said filtering step results from the addition of δ, i.e., the inverse Fourier transform of Δ, δ=iFFT(Δ), to the former impulse response f, of said filtering step.

12. Method according to claim 3 wherein during an initialization step a training signal sequence and preferably a pseudo-random sequence is used as an input signal to obtain an initial value f₁ of the impulse response fᵢ of said adaptive filtering step.

13. Method according to claim 12, wherein said adaptive filtering step uses a difference signal between said captured processing signal and said training signal sequence, which is delayed according to the delay of said captured processing signal with respect to said input signal, as a criterion to optimize the filter coefficients of said adaptive filtering step by minimizing the spectral power density of said difference signal.

14. Method according to claim 3, wherein said adaptive filtering step comprises an optimization algorithm selected from a group comprising a Least Mean Squares (LMS) algorithm, a steepest descent algorithm, a differential steepest descent algorithm, a gradient algorithm, a stochastic gradient algorithm and a Recursive Least Squares (RLS) algorithm.

15. Re-transmitter (Repeater) for single frequency signals, in particular of the type used in single frequency signal repeaters for use in single frequency networks (SFNs) like digital video/audio broadcasting (DVB/DAB) networks comprising:
at least one first antenna which receives a first single frequency signal,
a converter which converts said first single frequency signal to another frequency, preferably by down-mixing to an IF signal,
an input filter, preferably a band-pass filter, which filters said first single frequency or said IF signal and having a filtered input signal as an output,
an input amplifier, which amplifies said filtered input signal to produce an amplified input signal, preferably such that the amplification gain is controlled automatically to result in a substantially constant amplitude of said amplified input signal,
a quantizer, preferably an analogue-to-digital converter, which quantizes said amplified input signal or said filtered input signal to produce a quantized input signal,
a demodulator which demodulates said amplified input signal, said filtered input signal or said quantized input signal to result in a demodulated input signal,
an equalizer which equalizes said filtered, amplified, quantized and/or demodulated input signal, wherein said equalizer (50) is equipped to at least reduce a coupling signal between said first and second antenna,
a generator that generates a cancellation signal based on said equalized signal and feed-back means to feed back said cancellation signal to said equalized signal,
a converter which converts said equalized signal into a second single frequency signal, preferably of substantially the same frequency as the first single frequency signal,
an output filter which filters said second single frequency signal to result in a filtered second single frequency signal,
an output amplifier which amplifies said filtered second single frequency signal to result in an amplified second single frequency signal,
at least one second antenna which transmits said amplified second single frequency signal, and
said equalizer further comprises a variable phase shifter which shifts the phase of said equalized signal by an at least one predetermined phase angle Ψ.

16. Re-transmitter according to claim 15, wherein said equalizer includes adaptive filter means having a transfer function F(z).

17. Re-transmitter according to claim 15, including capturing means for capturing said filtered, amplified, quantized and/or demodulated input signal continuously or at predetermined points in time to produce a captured signal.

18. Re-transmitter according to claim 15, including analyzer means which at least partially analyze said equalized signal and/or said captured signal.

19. Re-transmitter according to claim 15, including delayer means for delaying said analyzed captured signal.

20. Re-transmitter according to claim 15, wherein the equalizer comprises digital signal processing.

21. A method for re-transmitting single frequency signals according to claim 1 in a re-transmitter for single frequency networks (SFNs), preferably digital video/audio broadcasting (DVB/DAB) networks and most preferably DVB-T networks.
